(19) United States
(12) Patent Application Publication
(10) Pub. No.: US 2014/0216537 A1
(43) Pub. Date: Aug. 7, 2014

(54) METALLIZATION PROCESS FOR SOLAR CELLS

(71) Applicant: VARIAN SEMICONDUCTOR EQUIPMENT ASSOCIATES, INC., Gloucester, MA (US)

(72) Inventor: John Graff, Swampscott, MA (US)

(73) Assignee: VARIAN SEMICONDUCTOR EQUIPMENT ASSOCIATES, INC., Gloucester, MA (US)

(21) Appl. No.: 13/761,969

(22) Filed: Feb. 7, 2013

(51) Int. Cl. H01L 31/18; H01L 31/02

(52) U.S. Cl. CPC H01L 31/18; H01L 31/02008
USPC 136/256; 438/98

(57) ABSTRACT

Several embodiments of a metallization process are disclosed, which achieve lower contact resistance and higher conductivity than methods currently employed with solar cells. These parameters result in a solar cell having improved performance and efficiency. In one embodiment, two different metals are used to create the metallization layer, where the first metal is selected for superior ohmic contact to the substrate and the second metal is selected based on conductivity. In a second embodiment, a first metal is evaporated or sputtered on the substrate. A second metal is then screen printed on the substrate. A removal step, such as etching is then performed to remove unwanted metal from the substrate.

### TECHNICAL FIELD

Embodiments of the present invention relate to a method for applying metallization to a solar cell, and more specifically to a metallization process for an IBC solar cell.

### BACKGROUND

Solar cells are semiconductor workpieces that include emitter regions, which may be p-type doped, and surface fields, which may be n-type doped. Solar cells utilize a pn junction, created between the emitter regions and the surface fields, to generate electrical current in the presence of photons. To carry this produced current from the workpiece, contact regions are disposed on the surface of the workpiece. These contact regions are exposed areas of doped semiconductor, and are used to electrically connect the semiconductor structures, which are contained within the workpiece, to the exterior of the workpiece. In some high efficiency solar cells, such as interdigitated back contact (IBC) solar cells, the contact regions for the emitter regions and the surface fields are located on one surface of the workpiece. In other solar cell structures, the contact regions of the emitter region and surface fields may be located on two opposing surfaces of the workpiece.

A metallization process is used to electrically connect these contact regions of the semiconductor workpiece to metal interconnects or busbars. The metallization process serves two functions. The first function is to make a low resistance contact with the exposed semiconductor area. The second function is to make a low resistance path from the contact region to the busbar or other metal interconnect.

Currently, the most common metallization process is performed using a metal paste. The metal paste is typically screen printed onto the surface of the workpiece and connects the contact region to the respective busbar or metal interconnect. The metal paste typically contains silver as the conductive metal.

However, while silver paste is a convenient and widely used mechanism to connect the contact region to the busbar, the electrical characteristics of silver are not ideal for this application. Silver does not form a very low contact resistance with the semiconductor contact regions. Furthermore, silver is expensive. To date, these disadvantages have been out-weighed by the convenience of a single metal paste process.

Therefore, it would be beneficial if there were a metallization process that achieved improved electrical characteristics, which would consequently improve the performance of the solar cell. It would also be beneficial if this process was low cost, high throughput and simple to implement.

### SUMMARY

Metallization processes that can be used to achieve improved electrical characteristics, and solar cells utilizing these metallization processes, are disclosed. In one embodiment, a metallization process that utilizes two different metals is employed. This metallization process for a solar cell comprises:
providing a workpiece having n-type doped regions, p-type doped regions, and an insulating layer covering the n-type doped regions and the p-type doped regions, the insulating layer having holes disposed therein so as to create contact regions on the workpiece;
depositing a first metal selectively in the contact regions; and
screen printing using a paste comprising a second metal to connect the first metal to a metal interconnect.

In another embodiment, a metal is evaporated, sputtered or otherwise deposited onto a workpiece. Excess metal is later removed from the workpiece. In this embodiment, the metallization process for a solar cell comprises:
providing a workpiece having n-type doped regions, p-type doped regions, and an insulating layer covering the n-type doped regions and the p-type doped regions, the insulating layer having holes disposed therein so as to create contact regions on the workpiece;
depositing a first metal on the insulating layer on a surface of the workpiece using evaporative deposition;
screen printing using a paste comprising a second metal to connect the first metal to a metal interconnect; and
removing metal from at least a portion of the surface to expose a portion of the insulating layer.

A solar cell may be created using the metallization process described above. In one embodiment, the solar cell comprises a bulk semiconductor; an emitter region disposed in the bulk semiconductor, near a surface of the solar cell; a surface field disposed in the bulk semiconductor, near the surface of the solar cell; an insulating layer covering the emitter region and the surface field, having a plurality of holes to expose a portion of the emitter region and a portion of the surface field; a first metal in electrical contact with the exposed emitter region and the exposed surface field; and a paste, comprising a second metal, different than the first metal, disposed on the insulating layer and in electrical contact with the first metal and a metal interconnect.

### BRIEF DESCRIPTION OF THE FIGURES

For a better understanding of the present disclosure, reference is made to the accompanying drawings, which are incorporated herein by reference and in which:

FIG. 1A is a cross section of a workpiece which may be used in the present disclosure;

FIG. 1B represents a bottom view of the workpiece of FIG. 1A;

FIG. 2 is a flowchart showing the metallization process according to one embodiment;

FIG. 3A is a cross-section of the workpiece of FIG. 1A after a deposition step is performed;

FIG. 3B represents a bottom view of the workpiece of FIG. 2A;

FIG. 4A is a cross-section of the workpiece of FIG. 3A after a screen printing step is performed;

FIG. 4B represents a bottom view of the workpiece of FIG. 4A;

FIG. 5 is a flowchart showing the metallization process according to another embodiment;

FIG. 6 is a cross-section of the workpiece of FIG. 1A after an evaporative deposition step is performed;

FIG. 7 is a cross-section of the workpiece of FIG. 6 after a screen printing step is performed; and

FIG. 8 is a cross-section of the workpiece of FIG. 7 after a material removal step is performed.

### DETAILED DESCRIPTION

Several embodiments of a metallization process are disclosed, which achieve lower contact resistance and higher conductivity than methods currently employed with solar cells. These parameters result in a solar cell having improved performance and efficiency.

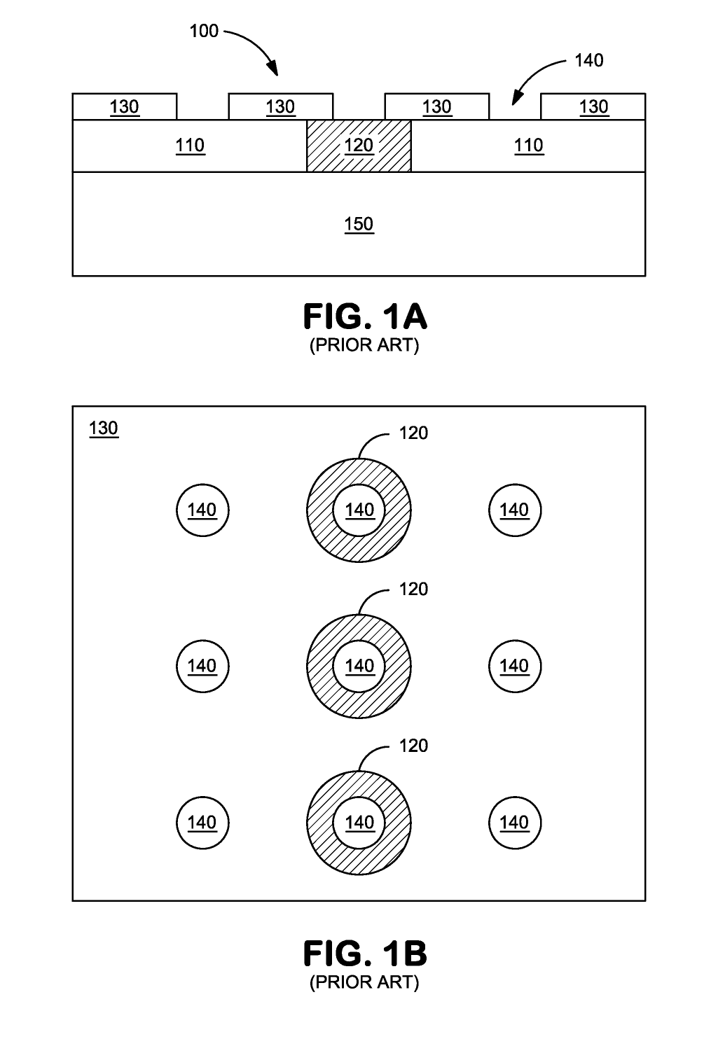

FIGS. 1A-B show a workpiece 100 which may be used with the embodiments described herein. FIG. 1A is a cross sectional view, while FIG. 1B represents a bottom view of the workpiece 100. As described above, the workpiece 100 contains a bulk region 150, p-type doped emitter regions 110 and n-type doped surface fields 120. Typically, in an IBC cell, the surface of the workpiece 100 is covered with a passivation and/or insulating layer 130. To create the contact regions, via holes are formed through the insulating layer 130, thereby exposing the underlying doped semiconductor. These exposed regions represent the contact regions 140. Note that the term “contact region” is used to refer to both the exposed p-type and exposed n-type regions of the workpiece. Those of ordinary skill in the art will recognize that there are many different process flows and materials that can be used to arrive at the workpiece shown in FIG. 1. For example, the doped regions can be formed using ion implantation, diffusion or other techniques. The contact regions 140 may be formed using an etch process to remove the insulating layer 130 from specific portions of the workpiece 100. This disclosure does not limit the method or materials used to create the workpiece shown in FIG. 1.

Although FIGS. 1A-B show a IBC solar cell, the disclosure is not limited to this particular embodiment. For example, in other solar cell structures, the n-type surface fields may be near one surface of the workpiece, while the p-type emitter regions may be near the opposite surface. In addition, in some embodiments, the emitter regions may be n-type doped, while the surface fields may be p-type doped. The present metallization processes may be used with any type of solar cell.

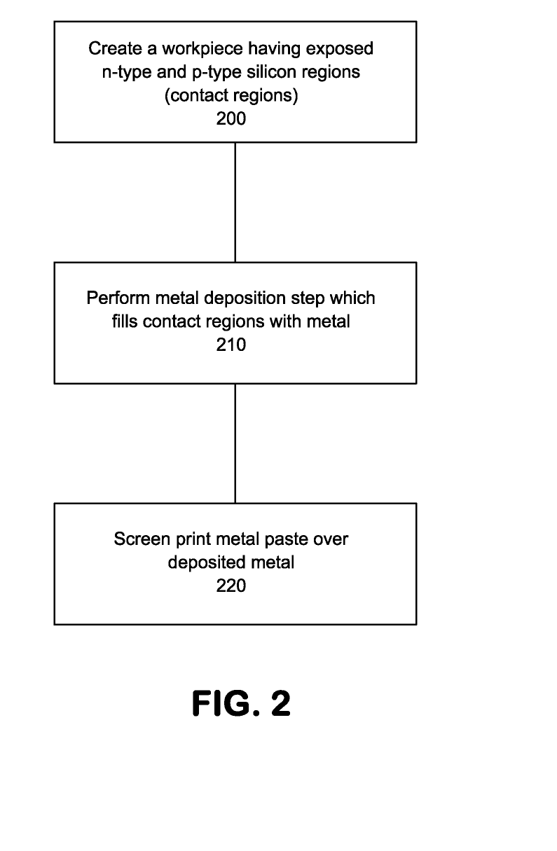

Rather than utilizing a traditional single step process utilizing a metal paste, several embodiments which utilize a multiple step process are described. A flowchart showing one such process is shown in FIG. 2. First, as shown in step 200, the workpiece 100 is processed to the stage shown in FIG. 1A-B. Then, in step 210, a deposition step which deposits a first metal into the contact regions (which are conductive silicon), but not on the insulating passivation layer is then performed. In one embodiment, an electrochemical deposition (ECD) step is performed. For example, a light induced plating process or electroless deposition may be used. In each embodiment, the deposition process is controlled such that the metal is selectively deposited in the regions where the doped silicon is exposed.

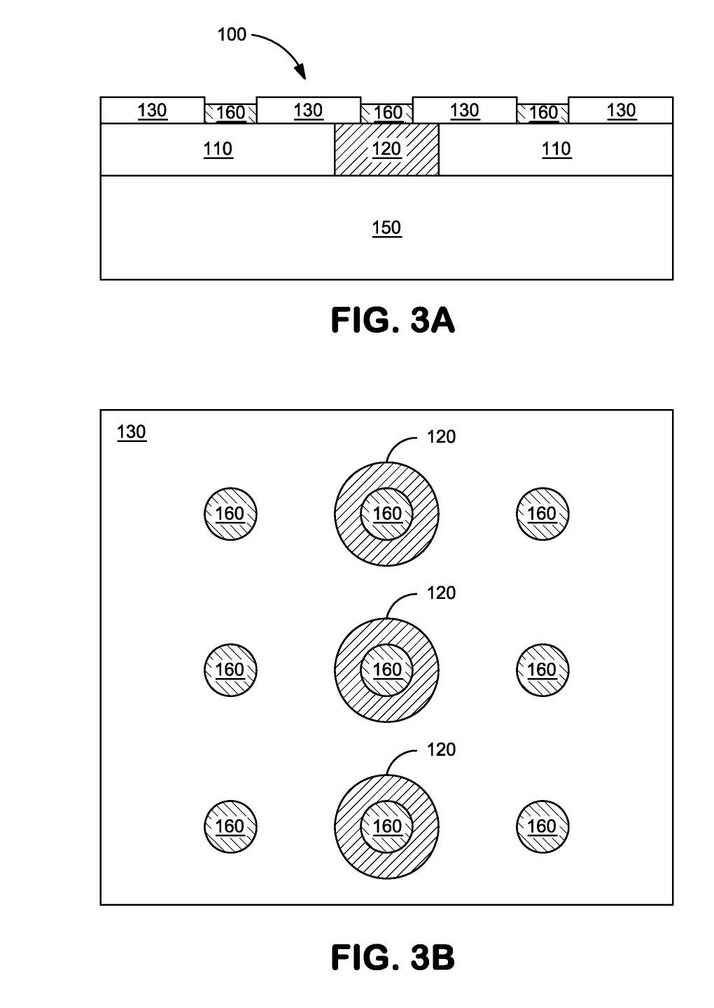

In one embodiment, the first metal is nickel, which is known that create an excellent ohmic contact to both p-type and n-type silicon after appropriate sintering processes. FIG. 3A shows a cross section of the workpiece of FIG. 1A and FIG. 3B shows a bottom view of the workpiece of FIG. 1B after the deposition process using the first metal has been completed. In these figures, the first metal 160 is shown filling the regions that were formerly the contact regions 140 (see FIG. 1B). Thus, the exposed doped portions of the workpiece 100 are in contact with nickel. While the use of nickel is described above, other suitable metals may also be deposited.

Next, as shown in step 220 of FIG. 2, a screen printing step is performed. Traditionally, as explained above, this was the only step performed. Therefore, since the contact regions were exposed, the metal in the paste used in this step had to exhibit good ohmic contact with the doped silicon. This requirement limited the choice of metal that could previously be used.

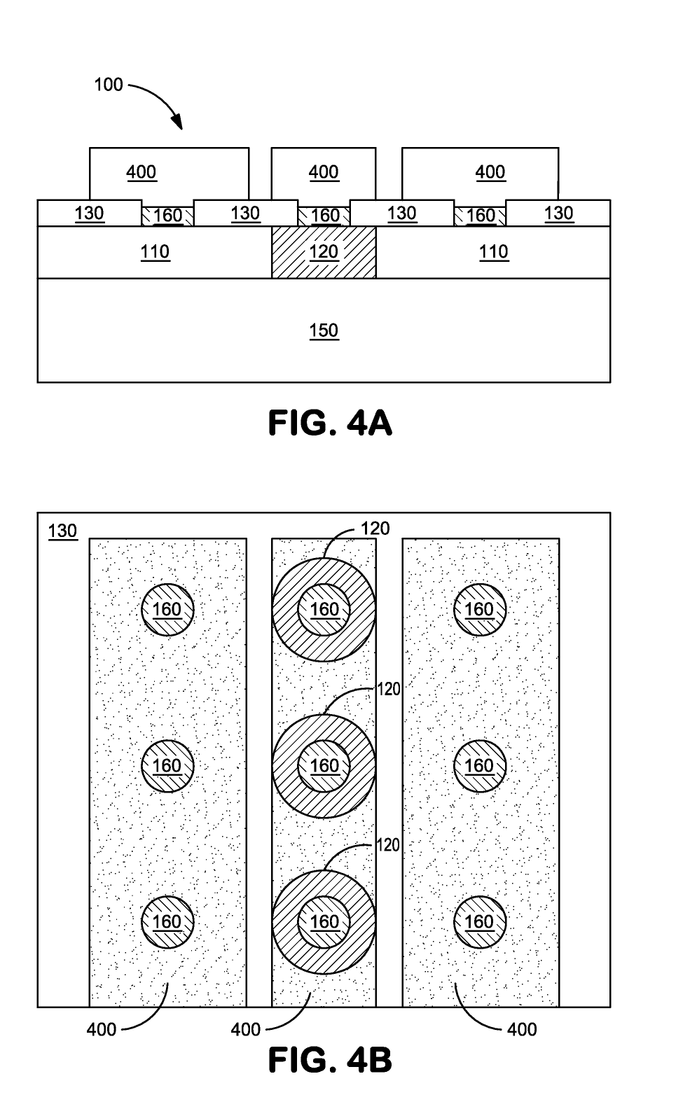

However, in the present embodiment, since a first metal has already been applied to the contact regions in step 210, a wide range of metals may be used in the paste which is screen printed. For example, highly conductive metals, such as copper or aluminum, can be used in the metal paste for this embodiment. The paste 400, which comprises a second metal, is screen printed so as to cover the metal 160 deposited in step 210, as shown in FIGS. 4A and 4B. Thus, the second metal is disposed on top of the deposited metal 160 and the insulating passivating layer 130. This paste 400 is in electrical contact with the first metal 160. The second metal serves to electrically connect the deposited first metal 160 to the metal interconnects (not shown) or busbars.

The process of FIG. 2 allows optimization of relevant electrical characteristics for each step of the process. When attaching to the contact regions, low ohmic contact resistance is desirable. The use of a deposition step allows the use of certain metals, such as nickel, which are known to create low ohmic contacts with doped silicon. Having created good ohmic contact, the second metal used in the screen printing step can be selected to maximize conductivity and/or minimize cost.

The workpiece created using the process of FIG. 2 includes a doped emitter region, a doped surface field, and an insulating layer disposed on these doped regions. Holes in the insulating layer expose portions of the doped regions, creating contact regions. A first metal, such as nickel is in electrical contact with these contact regions, but is not disposed on the insulating layer. A second metal, in the form of a paste, is disposed on the first metal and on the insulating layer. This paste electrically connects the first metal to a metal interconnect or busbar. Thus, unlike traditional solar cells, two different metals may be used in the metallization process, where the first metal is disposed against the contact regions and is selected based on its ohmic contact resistance and the second metal is disposed in a paste and is selected for parameters such as conductivity and cost.

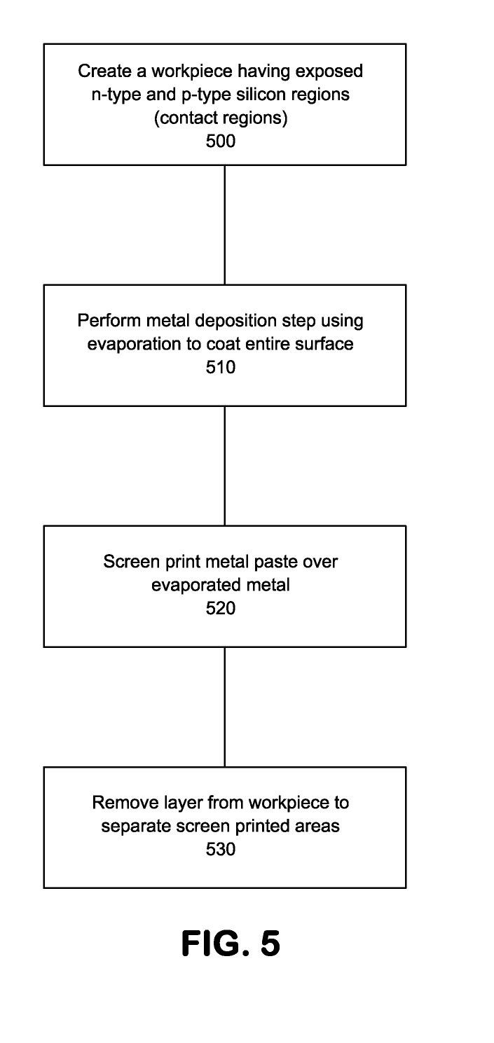

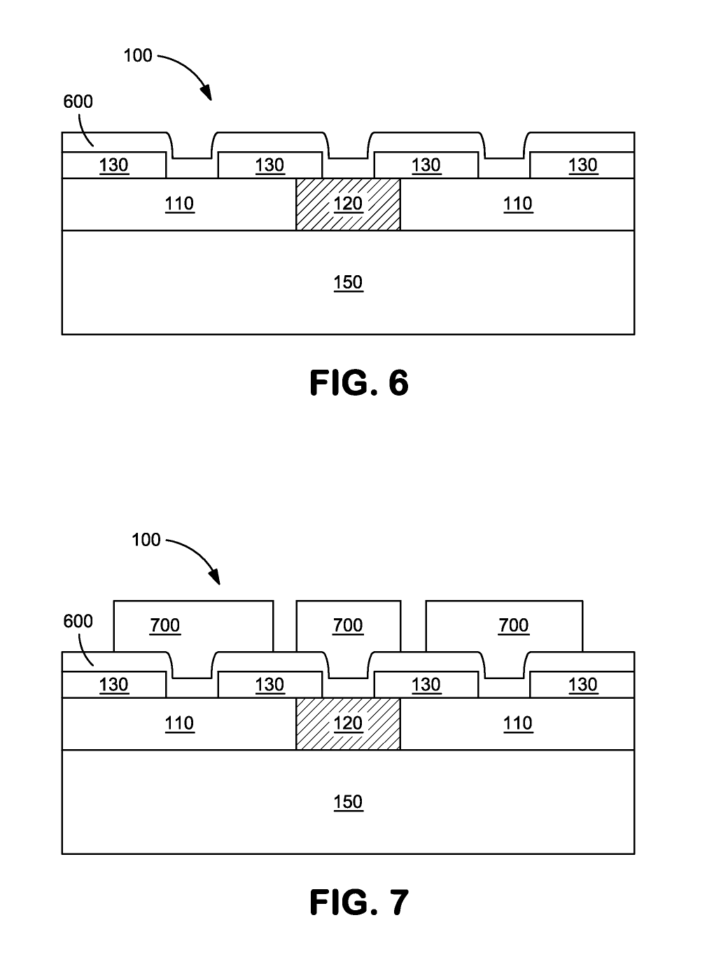

In another embodiment, shown in the flowchart of FIG. 5, a first metal is evaporated or sputtered and deposited onto the workpiece of FIG. 1A-B, as shown in step 510. In this embodiment, the metal film 600 is deposited on the entire surface of the workpiece 100, resulting in the workpiece shown in FIG. 6. The first metal may be aluminum or any other suitable metal.

As shown in step 520, after the metal has been evaporated over the surface of the workpiece 100, a paste 700 comprising a second metal is screen printed on the workpiece 100 (see FIG. 7). In some embodiments, the second metal is the same as the first metal. In one particular embodiment, aluminum is deposited using evaporation and then an aluminum based paste is screen printed over the deposited film.

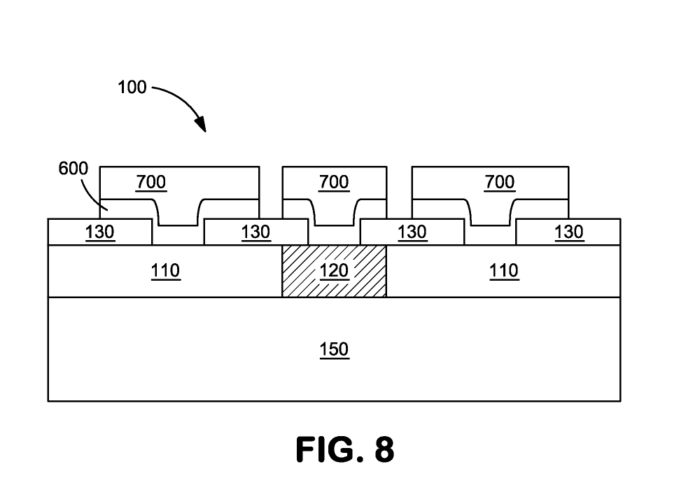

Since the first metal was deposited over the entire surface, it is necessary to remove unwanted metal, as shown in step 530. This may be done by removing material uniformly from the entire surface. As seen in FIG. 7, in certain areas, the workpiece 100 is covered by both the metal film 600 and the screen printed paste 700, while other areas are only covered by the metal film 600. Therefore, a step which removes material having a thickness equal to that of the metal film 600 from the entire surface would serve to electrically separate the contact regions from each other. This removal step may be an etch process, and, in this embodiment, results in the workpiece shown in FIG. 8. Note that the screen printed areas 700 are now separated from each other, much like the screen printed areas 400 shown in FIG. 4A. Stated differently, the removal step 530 serves to expose a portion of the insulating layer 130. Note that, in another embodiment, only material in the unwanted areas is removed, such as by a masking and etching process. However, this process may be more complex than that shown in FIG. 5.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A metallization process for a solar cell comprising:
providing a workpiece having n-type doped regions, p-type doped regions, and an insulating layer covering the n-type doped regions and the p-type doped regions, the insulating layer having holes disposed therein so as to create contact regions on the workpiece;
depositing a first metal selectively in the contact regions; and
screen printing using a paste comprising a second metal to connect the first metal to a metal interconnect.

2. The metallization process of claim 1, wherein the first metal comprises nickel.

3. The metallization process of claim 1, wherein the first metal is deposited using electroless deposition.

4. The metallization process of claim 1, wherein the first metal is deposited using electrochemical deposition.

5. The metallization process of claim 1, wherein the first metal is deposited using a light induced plating process.

6. The metallization process of claim 1, wherein the second metal is selected from the group consisting of copper and aluminum.

7. A metallization process for a solar cell comprising:
providing a workpiece having n-type doped regions, p-type doped regions, and an insulating layer covering the n-type doped regions and the p-type doped regions, the insulating layer having holes disposed therein so as to create contact regions on the workpiece;
depositing a first metal on the insulating layer on a surface of the workpiece using evaporative deposition;
screen printing using a paste comprising a second metal to connect the first metal to a metal interconnect; and
removing metal from at least a portion of the surface to expose a portion of the insulating layer.

8. The metallization process of claim 7, wherein the first metal is aluminum.

9. The metallization process of claim 7, wherein the second metal is selected from the group consisting of copper and aluminum.

10. The metallization process of claim 7, wherein the removing step comprises an etching process.

11. The metallization process of claim 10, wherein the removing step removes metal from the entire surface of the workpiece.

12. A solar cell, comprising:
a bulk semiconductor;
an emitter region disposed in the bulk semiconductor, near a surface of the solar cell;
a surface field disposed in the bulk semiconductor, near the surface of the solar cell;
an insulating layer covering the emitter region and the surface field, having a plurality of holes to expose a portion of the emitter region and a portion of the surface field;
a first metal in electrical contact with the exposed emitter region and the exposed surface field; and
a paste, comprising a second metal, different than the first metal, disposed on the insulating layer and in electrical contact with the first metal and a metal interconnect.

13. The solar cell of claim 12, wherein the first metal comprises nickel.

14. The solar cell of claim 12, wherein the second metal comprises copper.

15. The solar cell of claim 12, wherein the second metal comprises aluminum.
